(19) United States
(12) Patent Application Publication
(10) Pub. No.: US 2026/0087190 A1
(43) Pub. Date: Mar. 26, 2026

(54) SYSTEMS AND METHODS FOR AUTOMATIC REQUIREMENTS CAPTURE AND GENERATION OF SYSTEM BUILDS USING ARTIFICIAL INTELLIGENCE

(71) Applicant: BANK OF AMERICA CORPORATION, Charlotte, NC (US)

(72) Inventors: Mohammad Saleem Gaziani, Plano, TX (US); Amer Ali, Jersey City, NJ (US); Aaron Gee, Palm Coast, FL (US); Aisha Jenkins, Atlanta, GA (US); John Lozes, Wilmington, DE (US); Tonya Kyra Miller, Charlotte, NC (US); Manonmani Palanichamy, Fort Mill, SC (US); Naresh Kumar Petapalle, Welling (GB); Aravind Singtalur, McKinney, TX (US); Asha Thekkumpurath, Frisco, TX (US); Andrea M. Weisberger, Jacksonville, FL (US)

(73) Assignee: BANK OF AMERICA CORPORATION, Charlotte, NC (US)

(21) Appl. No.: 18/892,808

(22) Filed: Sep. 23, 2024

(51) Int. Cl. G06F 30/13; G06F 30/27

(52) U.S. Cl. CPC G06F 30/13; G06F 30/27

(57) ABSTRACT

Systems, computer program products, and methods are described herein for automatic requirements capture and generation of system builds using artificial intelligence. The present invention is configured to receive a plurality of architectural requirements for a system build; render an interactive graphical user interface (GUI) for display on user devices, wherein the GUI includes information for a plurality of system builds; receive an input from a user device displaying the GUI, wherein the input includes information for the system build; validate the input for the system build; transmit, upon invalidation of the input, a notification of an invalid input to the user device; transmit, upon validation of the input, the input to networked devices associated with the system build; receive a build output file for the system build; and store the build output file in at least one memory device.

### FIELD OF THE INVENTION

The present disclosure embraces a system for automatic requirements capture and generation of system builds using artificial intelligence.

### BACKGROUND

Traditional infrastructure provisioning and infrastructure builds, whether manual or automated, depend on pre-determined steps. This rigid approach makes it difficult for the infrastructure to be flexible and adaptable to the changing demands.

### SUMMARY

The following presents a simplified summary of one or more embodiments of the present invention, in order to provide a basic understanding of such embodiments. This summary is not an extensive overview of all contemplated embodiments and is intended to neither identify key or critical elements of all embodiments nor delineate the scope of any or all embodiments. Its sole purpose is to present some concepts of one or more embodiments of the present invention in a simplified form as a prelude to the more detailed description that is presented later.

In one aspect, a system for automatic requirements capture and generation of system builds using artificial intelligence may include at least one memory device with computer-readable program code stored thereon and at least one processing device operatively coupled to the at least one memory device. In some embodiments, executing the computer-readable code may be configured to cause the at least one processing device to receive a plurality of architectural requirements for a system build, render an interactive graphical user interface (GUI) for display on user devices, where the GUI includes information for a plurality of system builds, receive an input from a user device displaying the GUI, where the input includes information for the system build, validate the input for the system build, transmit, upon invalidation of the input, a notification of an invalid input to the user device, transmit, upon validation of the input, the input to networked devices associated with the system build, receive a build output file for the system build, and store the build output file in the at least one memory device.

In some embodiments, validating the input may include an AI model configured to analyze each element of the input for incorrect data, determine, if an element of the input is incorrect, the input is invalid, analyze a label of the input to determine a category, where at least one category is a design category, analyze, if the category is a design category, the input for elements of a design for the system build, compare the elements of the design against the plurality of architectural requirements, and determine, if an element of the design does not meet an architectural requirement, the input is invalid.

In some embodiments, the AI model may be configured to analyze, if the category is a design category, design requirements for the input, calculate an estimate of a cost for implementation, extract a team from a label of the input, analyze a financial status of the team, determine if the financial status of the team exceeds the estimate of the cost for implementation, and determine, if the financial status of the team does not exceed the estimate of the cost for implementation, the input is invalid.

In some embodiments, the system may include an AI engine configured to receive business requirements for a design for the system build, receive historical data for the design, receive core layer requirements for the design, receive application specific requirements for the design and compile the business requirements, historical data, core layer requirements, and the application specific requirements into the plurality of architectural requirements for the system build.

In some embodiments, the system may include a generative AI tool configured to receive an input file for the system build, process the input file for a plurality of parameters for the system build, request a plurality of additional parameters for the system build, generate computer code using the plurality of parameters and plurality of additional parameters for the system build, compile the computer code into the build output file, and transmit the build output file. Further, the generative AI tool may be integrated with at least one configuration management tool. Additionally, and/or alternatively, the generative AI may be configured to analyze available data for incorrect data, identify data of the available data that is incorrect data, and flag the incorrect data of the available data for manual adjustment.

The features, functions, and advantages that have been discussed may be achieved independently in various embodiments of the present invention or may be combined with yet other embodiments, further details of which can be seen with reference to the following description and drawings.

### BRIEF DESCRIPTION OF THE DRAWINGS

Having thus described embodiments of the invention in general terms, reference will now be made the accompanying drawings, wherein:

FIGS. 1A-1C illustrate technical components of an exemplary distributed computing environment for automatic requirements capture and generation of system builds using artificial intelligence, in accordance with an embodiment of the disclosure;

FIG. 2 illustrates an exemplary artificial intelligence (AI) engine subsystem architecture, in accordance with an embodiment of the disclosure;

FIG. 3 illustrates a flowchart for automatic requirements capture and generation of system builds using artificial intelligence, in accordance with an embodiment of the disclosure;

FIG. 4 illustrates a process flow for automatic requirements capture and generation of system builds using artificial intelligence, in accordance with an embodiment of the disclosure;

FIG. 5 illustrates a process flow for automatic requirements capture and generation of system builds using artificial intelligence, in accordance with an embodiment of the disclosure;

FIG. 6 illustrates a process flow for automatic requirements capture and generation of system builds using artificial intelligence, in accordance with an embodiment of the disclosure;

FIG. 7 illustrates a process flow for automatic requirements capture and generation of system builds using artificial intelligence, in accordance with an embodiment of the disclosure;

FIG. 8 illustrates a process flow for automatic requirements capture and generation of system builds using artificial intelligence, in accordance with an embodiment of the disclosure; and

FIG. 9 illustrates a process flow for automatic requirements capture and generation of system builds using artificial intelligence, in accordance with an embodiment of the disclosure.

### DETAILED DESCRIPTION OF EMBODIMENTS OF THE INVENTION

Embodiments of the present invention will now be described more fully hereinafter with reference to the accompanying drawings, in which some, but not all, embodiments of the invention are shown. Indeed, the invention may be embodied in many different forms and should not be construed as limited to the embodiments set forth herein; rather, these embodiments are provided so that this disclosure will satisfy applicable legal requirements. Where possible, any terms expressed in the singular form herein are meant to also include the plural form and vice versa, unless explicitly stated otherwise. Also, as used herein, the term “a” and/or “an” shall mean “one or more,” even though the phrase “one or more” is also used herein. Furthermore, when it is said herein that something is “based on” something else, it may be based on one or more other things as well. In other words, unless expressly indicated otherwise, as used herein “based on” means “based at least in part on” or “based at least partially on.” Like numbers refer to like elements throughout.

As used herein, an “entity” may be any institution employing information technology resources and particularly technology infrastructure configured for processing large amounts of data. Typically, these data can be related to the people who work for the organization, its products or services, the customers or any other aspect of the operations of the organization. As such, the entity may be any institution, group, association, financial institution, establishment, company, union, authority or the like, employing information technology resources for processing large amounts of data.

As described herein, a “user” may be an individual associated with an entity. As such, in some embodiments, the user may be an individual having past relationships, current relationships or potential future relationships with an entity. In some embodiments, the user may be an employee (e.g., an associate, a project manager, an IT specialist, a manager, an administrator, an internal operations analyst, and/or the like) of the entity or enterprises affiliated with the entity.

As used herein, a “user interface” may be a point of human-computer interaction and communication in a device that allows a user to input information, such as commands or data, into a device, or that allows the device to output information to the user. For example, a user interface may include a graphical user interface (GUI), which may include an interface to input computer-executable instructions that direct a processor to carry out specific functions. The user interface may employ certain input and/or output devices such as a display, a mouse, a keyboard, a button, a touchpad, a touch screen, a microphone, a speaker, an LED, a light, a joystick, a switch, a buzzer, a bell, and/or other user input/output device for communicating with one or more users.

As used herein, an “engine” may refer to core elements of an application, or part of an application that serves as a foundation for a larger piece of software and drives the functionality of the software. In some embodiments, an engine may be self-contained, but externally-controllable code that encapsulates powerful logic designed to perform or execute a specific type of function. In one aspect, an engine may be underlying source code that establishes file hierarchy, input and output methods, and how a specific part of an application interacts or communicates with other software and/or hardware. The specific components of an engine may vary based on the needs of the specific application as part of the larger piece of software. In some embodiments, an engine may be configured to retrieve resources created in other applications, which may then be ported into the engine for use during specific operational aspects of the engine. An engine may be configurable to be implemented within any general purpose computing system. In doing so, the engine may be configured to execute source code embedded therein to control specific features of the general purpose computing system to execute specific computing operations, thereby transforming the general purpose system into a specific purpose computing system.

As used herein, “authentication credentials” may be any information that can be used to identify of a user. For example, a system may prompt a user to enter authentication information such as a username, a password, a personal identification number (PIN), a passcode, biometric information (e.g., iris recognition, retina scans, fingerprints, finger veins, palm veins, palm prints, digital bone anatomy/structure and positioning (distal phalanges, intermediate phalanges, proximal phalanges, and the like), an answer to a security question, a unique intrinsic user activity, such as making a predefined motion with a user device. This authentication information may be used to authenticate the identity of the user (e.g., determine that the authentication information is associated with the account) and determine that the user has authority to access an account or system. In some embodiments, the system may be owned or operated by an entity. In such embodiments, the entity may employ additional computer systems, such as authentication servers, to validate and certify resources inputted by the plurality of users within the system. The system may further use its authentication servers to certify the identity of users of the system, such that other users may verify the identity of the certified users. In some embodiments, the entity may certify the identity of the users. Furthermore, authentication information or permission may be assigned to or required from a user, application, computing node, computing cluster, or the like to access stored data within at least a portion of the system.

It should also be understood that “operatively coupled,” as used herein, means that the components may be formed integrally with each other, or may be formed separately and coupled together. Furthermore, “operatively coupled” means that the components may be formed directly to each other, or to each other with one or more components located between the components that are operatively coupled together. Furthermore, “operatively coupled” may mean that the components are detachable from each other, or that they are permanently coupled together. Furthermore, operatively coupled components may mean that the components retain at least some freedom of movement in one or more directions or may be rotated about an axis (i.e., rotationally coupled, pivotally coupled). Furthermore, “operatively coupled” may mean that components may be electronically connected and/or in fluid communication with one another.

As used herein, an “interaction” may refer to any communication between one or more users, one or more entities or institutions, one or more devices, nodes, clusters, or systems within the distributed computing environment described herein. For example, an interaction may refer to a transfer of data between devices, an accessing of stored data by one or more nodes of a computing cluster, a transmission of a requested task, or the like.

As used herein, “determining” may encompass a variety of actions. For example, “determining” may include calculating, computing, processing, deriving, investigating, ascertaining, and/or the like. Furthermore, “determining” may also include receiving (e.g., receiving information), accessing (e.g., accessing data in a memory), and/or the like. Also, “determining” may include resolving, selecting, choosing, calculating, establishing, and/or the like. Determining may also include ascertaining that a parameter matches a predetermined criterion, including that a threshold has been met, passed, exceeded, and so on.

As used herein, a “resource” may generally refer to objects, products, devices, goods, commodities, services, and the like, and/or the ability and opportunity to access and use the same. Some example implementations herein contemplate property held by a user, including property that is stored and/or maintained by a third-party entity. In some example implementations, a resource may be associated with one or more accounts or may be property that is not associated with a specific account. Examples of resources associated with accounts may be accounts that have cash or cash equivalents, commodities, and/or accounts that are funded with or contain property, such as safety deposit boxes containing jewelry, art or other valuables, a trust account that is funded with property, or the like. For purposes of this invention, a resource is typically stored in a resource repository-a storage location where one or more resources are organized, stored and retrieved electronically using a computing device.

As used herein, a “resource transfer,” “resource distribution,” or “resource allocation” may refer to any transaction, activities or communication between one or more entities, or between the user and the one or more entities. A resource transfer may refer to any distribution of resources such as, but not limited to, a payment, processing of funds, purchase of goods or services, a return of goods or services, a payment transaction, a credit transaction, or other interactions involving a user's resource or account. Unless specifically limited by the context, a “resource transfer” a “transaction”, “transaction event” or “point of transaction event” may refer to any activity between a user, a merchant, an entity, or any combination thereof. In some embodiments, a resource transfer or transaction may refer to financial transactions involving direct or indirect movement of funds through traditional paper transaction processing systems (i.e. paper check processing) or through electronic transaction processing systems. Typical financial transactions include point of sale (POS) transactions, automated teller machine (ATM) transactions, person-to-person (P2P) transfers, internet transactions, online shopping, electronic funds transfers between accounts, transactions with a financial institution teller, personal checks, conducting purchases using loyalty/rewards points and/or the like. When discussing that resource transfers or transactions are evaluated it could mean that the transaction has already occurred, is in the process of occurring or being processed, or it has yet to be processed/posted by one or more financial institutions. In some embodiments, a resource transfer or transaction may refer to non-financial activities of the user. In this regard, the transaction may be a customer account event, such as but not limited to the customer changing a password, ordering new checks, adding new accounts, opening new accounts, adding or modifying account parameters/restrictions, modifying a payee list associated with one or more accounts, setting up automatic payments, performing/modifying authentication procedures and/or credentials, and the like.

As used herein, “payment instrument” may refer to an electronic payment vehicle, such as an electronic credit or debit card. The payment instrument may not be a “card” at all and may instead be account identifying information stored electronically in a user device, such as payment credentials or tokens/aliases associated with a digital wallet, or account identifiers stored by a mobile application.

The present disclosure provides a system for automatic requirements capture and generation of system builds using artificial intelligence. In an example embodiment, the invention discloses a system that may incorporate full end-to-end automation for capturing initial requirements from the application line of business (LOB) team and/or trigger workflows. Further, the design may be collaborative between various stake holders (e.g., a person, group, and/or organization with an interest in the outcome of the system), as well as, in applicable cases, AI modules that may analyze and capture a legacy system's history (e.g., the positive aspects of the legacy system and/or the negative aspects of the legacy system) and may incorporate that history in the design. Additionally, and/or alternatively, there may be multiple layers of design templates applied.

In some embodiments, core layers may cover concerns such as resiliency, uptime, anti-affinity, channel segregation and/or the like. Further, LOB and/or domain specific design patterns may be applied. In such embodiments, on top of those layers, application specific custom patterns specified by human designers and/or AI suggested patterns may be applied. Additionally, and/or alternatively, collaborative designing may be workflow driven to include a single view of the system design. In some embodiments, one or more workflows may require approval from one or more of the stake holders.

Traditional infrastructure provisioning and infrastructure builds, whether manual or automated, depend on pre-determined steps. This rigid approach makes it difficult for the infrastructure to be flexible and adaptable to changing demands. It also assumes all items in the builds have uniform configuration which may not be the real-world scenario. On shared infrastructures, deployed applications may need flexibility for variations in the configurations. Often there may be a disconnect between various stake holders on the requirements and design of the intended infrastructure due to a lack of a shared workflow-oriented view of the infrastructure requests. Additionally, the requirements may be based upon subjective views or expertise of the project management team that may not have a complete view or a historic and current view of the system being proposed.

Embodiments of the present disclosure may include a system including a dashboard operatively coupled to a workflow engine. Further, the dashboard may be in communication with at least one AI algorithm engine. Additionally, and/or alternatively, the dashboard may be in communication with at least one generative AI tool.

In some embodiments, the system may automate and/or streamline workflows by using artificial intelligence for information technology (IT) operations (AIOps) (e.g., using big data models and/or machine learning (ML) models to automate operational workflows, streamline operational workflows, and/or monitor event correlation and causality determination). Further, generative AI models may be used to automate coding and/or modernize legacy applications to scale and/or to target new platforms. In such embodiments, the generative AI models may improve data consistency, decrease coding errors, and/or increase production speed.

Embodiments of the present disclosure may be configured to incorporate AI and/or ML models to improve cybersecurity (e.g., AI and/or ML models configured to detect misrepresentations and/or misappropriations, detect and/or block malware, use reinforcement learning to train, identify and respond to cyberattacks, use algorithms for anomaly detection, and/or the like). Further, AI and/or ML models may be configured to perform predictive maintenance and cleanup. For example, an AI model may analyze all data and may identify problems by flagging required changes. Additionally, and/or alternatively, the system may include an AI model configured to detect and analyze drifts in a build and/or server, considering factors such as workload patterns, performance metrics, and/or security requirements.

In some embodiments, the system may be configured to automatically adjust build and/or server configurations to optimal settings based on AI insights, rather than reverting to an original predefined state. In such embodiments, the system may be configured to use AI analysis to update the predefined state with new optimal configurations, ensuring the predefined state evolves with changing requirements. Additionally, and/or alternatively, the system may include a recommendation engine configured to provide configuration change recommendations for temporary or permanent drift, based on predictive analytics and/or historical data. Further, the system may be configured to provide alerts for significant design changes and may allow for manual approval of critical updates, maintaining control over an adaptation process.

In some embodiments, the system may integrate with DevOps tools and/or configuration management tools to streamline the implementation of configuration changes. Further, the dashboard may be integrated with an API, where the API updates the dashboard with all required configurations, virtual machines (VMs) and build statuses. The builds for each of the environments may be initiated by including data for playbooks using APIs and then triggering workflows to execute jobs for each of the nodes. Embodiments of the present disclosure may provide full end to end automation utilizing intelligent and modern AI and/or APIs for infrastructure requirements that may capture, auto design, implement and/or build-out servers and/or builds. Further, the dashboard may be configured to, in real time, keep track of server inventory, various configurations, overall build status, and may report drifts along with any change recommendations.

Accordingly, the present invention may include a system, a computer program, and/or a method for using a dashboard and/or AI to automate requirement capture and automate generation of system builds. Embodiments of the present disclosure may include a plurality of artificial intelligence (AI) models configured to receive, compile, and/or reformat architectural requirements, generate computer code for a system build, and/or monitor and error check operation workflow. In an example embodiment, an AI engine may be configured to receive architectural requirements (e.g., initial requirements, LOB requirements, core layer requirements, application specific requirements, legacy system's history, and design templates) for a system build. Further, the AI model may be configured to compile and/or reformat the separate architectural requirements for a system build into a single file. Additionally, a dashboard operatively coupled with a workflow engine may be configured to receive the file including the architectural requirements. In some embodiments, the dashboard operatively coupled with a workflow engine may be configured to receive an input from a user device and validate (e.g., error check, compliance check with architectural requirements, team financial validation, and/or the like) the input. Additionally, a generative AI tool may be configured to receive an input file including information for a design of a system build. Further, the generative AI tool may be configured to generate, from the input file, a build output file for the system build.

What is more, the present invention provides a technical solution to a technical problem. As described herein, the technical problem includes infrastructure builds that depend on rigid, pre-determined steps and lead to difficulties for the infrastructure to be flexible and adaptable to changing demands. The technical solution presented herein allows for a dashboard, operatively coupled to a workflow engine and/or AI engine(s), configured to incorporate full end-to-end automation that may capture initial requirements from the application LOB team and may trigger workflows. In particular, the system for automatic requirements capture and generation of system builds using artificial intelligence is an improvement over existing solutions to the infrastructure builds depending on rigid, pre-determined steps that leads to difficulties for the infrastructure to be flexible and adaptable to changing demands (i) with fewer steps to achieve the solution, thus reducing the amount of computing resources, such as processing resources, storage resources, network resources, and/or the like, that are being used (e.g., by streamlining communication and workflow through the dashboard operatively coupled to the workflow engine, human error is minimized thus reducing the number of steps needed), (ii) providing a more accurate solution to the problem, thus reducing the number of resources required to remedy any errors made due to a less accurate solution (e.g., by leveraging AI and/or ML models, the system may quickly and accurately detect and remedy anomalies, errors, and/or the like), (iii) removing manual input and waste from the implementation of the solution, thus improving speed and efficiency of the process and conserving computing resources (e.g., by leveraging AI and/or ML models, the system may eliminate the need for manual correction of errors in communications and system builds), (iv) determining an optimal amount of resources that need to be used to implement the solution, thus reducing network traffic and load on existing computing resources (e.g., by leveraging AI and/or ML models in predictive analytics, the system may continuously update and/or make recommendations of updates to system builds to optimize the performance of the system build such that the amount of resources used by the server is minimized). Furthermore, the technical solution described herein uses a rigorous, computerized process to perform specific tasks and/or activities that were not previously performed. In specific implementations, the technical solution bypasses a series of steps previously implemented, thus further conserving computing resources.

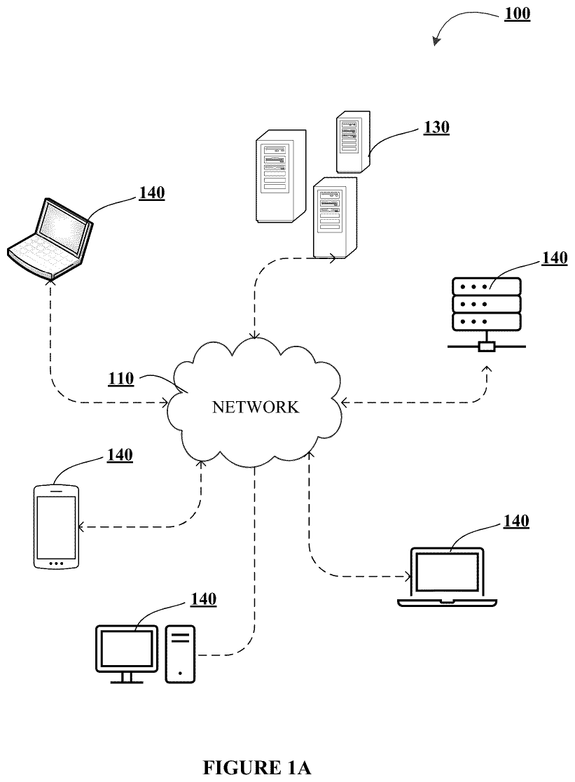

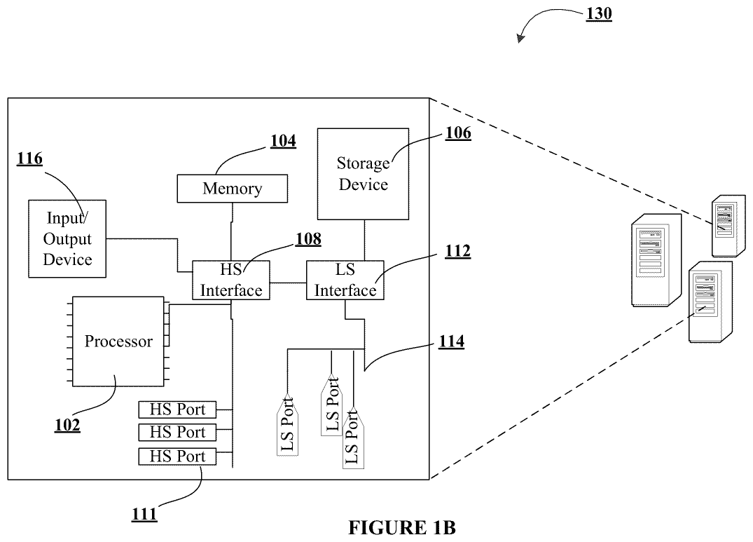

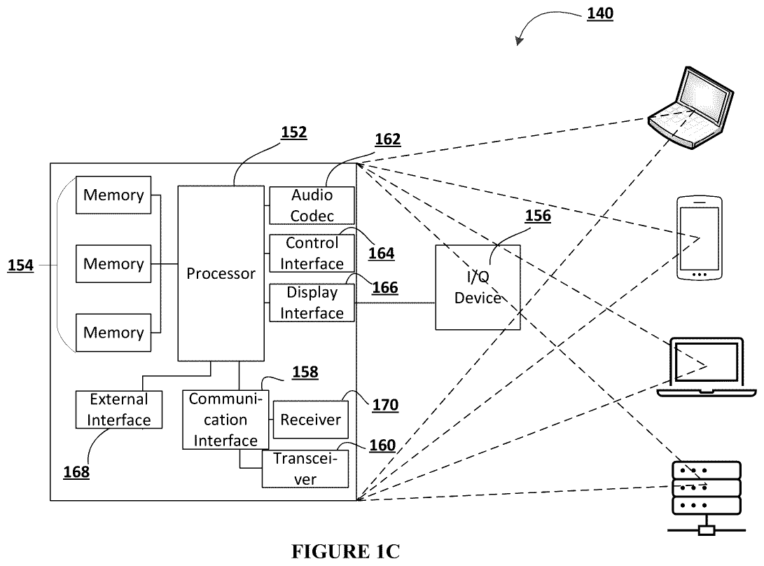

FIGS. 1A-1C illustrate technical components of an exemplary distributed computing environment for automatic requirements capture and generation of system builds using artificial intelligence 100, in accordance with an embodiment of the invention. As shown in FIG. 1A, the distributed computing environment 100 contemplated herein may include a system 130 (e.g., a dashboard generating system operatively coupled to a workflow engine and/or AI engine(s)), an end-point device(s) 140, and a network 110 over which the system 130 and end-point device(s) 140 communicate therebetween. FIG. 1A illustrates only one example of an embodiment of the distributed computing environment 100, and it will be appreciated that in other embodiments one or more of the systems, devices, and/or servers may be combined into a single system, device, or server, or be made up of multiple systems, devices, or servers. Also, the distributed computing environment 100 may include multiple systems, same or similar to system 130, with each system providing portions of the necessary operations (e.g., as a server bank, a group of blade servers, or a multi-processor system).

In some embodiments, the system 130 and the end-point device(s) 140 may have a client-server relationship in which the end-point device(s) 140 are remote devices that request and receive service from a centralized server, i.e., the system 130. In some other embodiments, the system 130 and the end-point device(s) 140 may have a peer-to-peer relationship in which the system 130 and the end-point device(s) 140 are considered equal and all have the same abilities to use the resources available on the network 110. Instead of having a central server (e.g., system 130) which would act as the shared drive, each device that is connect to the network 110 would act as the server for the files stored on it.

The system 130 may represent various forms of servers, such as web servers, database servers, file server, or the like, various forms of digital computing devices, such as laptops, desktops, video recorders, audio/video players, radios, workstations, or the like, or any other auxiliary network devices, such as wearable devices, Internet-of-things devices, electronic kiosk devices, mainframes, or the like, or any combination of the aforementioned.

The end-point device(s) 140 may represent various forms of electronic devices, including user input devices such as personal digital assistants, cellular telephones, smartphones, laptops, desktops, and/or the like, merchant input devices such as point-of-sale (POS) devices, electronic payment kiosks, and/or the like, electronic telecommunications device (e.g., automated teller machine (ATM)), and/or edge devices such as routers, routing switches, integrated access devices (IAD), and/or the like.

The network 110 may be a distributed network that is spread over different networks. This provides a single data communication network, which can be managed jointly or separately by each network. Besides shared communication within the network, the distributed network often also supports distributed processing. The network 110 may be a form of digital communication network such as a telecommunication network, a local area network (“LAN”), a wide area network (“WAN”), a global area network (“GAN”), the Internet, or any combination of the foregoing. The network 110 may be secure and/or unsecure and may also include wireless and/or wired and/or optical interconnection technology.

It is to be understood that the structure of the distributed computing environment and its components, connections and relationships, and their functions, are meant to be exemplary only, and are not meant to limit implementations of the inventions described and/or claimed in this document. In one example, the distributed computing environment 100 may include more, fewer, or different components. In another example, some or all of the portions of the distributed computing environment 100 may be combined into a single portion or all of the portions of the system 130 may be separated into two or more distinct portions.

FIG. 1B illustrates an exemplary component-level structure of the system 130, in accordance with an embodiment of the invention. As shown in FIG. 1B, the system 130 may include a processor 102, memory 104, input/output (I/O) device 116, and a storage device 106. The system 130 may also include a high-speed interface 108 connecting to the memory 104, and a low-speed interface 112 (shown as “LS Interface”) connecting to low speed bus 114 (shown as “LS Port”) and storage device 110. Each of the components 102, 104, 108, 110, and 112 may be operatively coupled to one another using various buses and may be mounted on a common motherboard or in other manners as appropriate. As described herein, the processor 102 may include a number of subsystems to execute the portions of processes described herein. Each subsystem may be a self-contained component of a larger system (e.g., system 130) and capable of being configured to execute specialized processes as part of the larger system.

The processor 102 can process instructions, such as instructions of an application that may perform the functions disclosed herein. These instructions may be stored in the memory 104 (e.g., non-transitory storage device) or on the storage device 110, for execution within the system 130 using any subsystems described herein. It is to be understood that the system 130 may use, as appropriate, multiple processors, along with multiple memories, and/or I/O devices, to execute the processes described herein.

The memory 104 stores information within the system 130. In one implementation, the memory 104 is a volatile memory unit or units, such as volatile random access memory (RAM) having a cache area for the temporary storage of information, such as a command, a current operating state of the distributed computing environment 100, an intended operating state of the distributed computing environment 100, instructions related to various methods and/or functionalities described herein, and/or the like. In another implementation, the memory 104 is a non-volatile memory unit or units. The memory 104 may also be another form of computer-readable medium, such as a magnetic or optical disk, which may be embedded and/or may be removable. The non-volatile memory may additionally or alternatively include an EEPROM, flash memory, and/or the like for storage of information such as instructions and/or data that may be read during execution of computer instructions. The memory 104 may store, recall, receive, transmit, and/or access various files and/or information used by the system 130 during operation.

The storage device 106 is capable of providing mass storage for the system 130. In one aspect, the storage device 106 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier may be a non-transitory computer-or machine-readable storage medium, such as the memory 104, the storage device 104, or memory on processor 102.

The high-speed interface 108 manages bandwidth-intensive operations for the system 130, while the low speed controller 112 manages lower bandwidth-intensive operations. Such allocation of functions is exemplary only. In some embodiments, the high-speed interface 108 (shown as “HS Interface”) is coupled to memory 104, input/output (I/O) device 116 (e.g., through a graphics processor or accelerator), and to high-speed expansion ports 111 (shown as “HS Port”), which may accept various expansion cards (not shown). In such an implementation, low-speed controller 112 is coupled to storage device 106 and low-speed expansion port 114. The low-speed expansion port 114, which may include various communication ports (e.g., USB, Bluetooth, Ethernet, wireless Ethernet), may be coupled to one or more input/output devices, such as a keyboard, a pointing device, a scanner, or a networking device such as a switch or router, e.g., through a network adapter.

The system 130 may be implemented in a number of different forms. For example, it may be implemented as a standard server, or multiple times in a group of such servers. Additionally, the system 130 may also be implemented as part of a rack server system or a personal computer such as a laptop computer. Alternatively, components from system 130 may be combined with one or more other same or similar systems and an entire system 130 may be made up of multiple computing devices communicating with each other.

FIG. 1C illustrates an exemplary component-level structure of the end-point device(s) 140, in accordance with an embodiment of the invention. As shown in FIG. 1C, the end-point device(s) 140 includes a processor 152, memory 154, an input/output device such as a display 156, a communication interface 158, and a transceiver 160, among other components. The end-point device(s) 140 may also be provided with a storage device, such as a microdrive or other device, to provide additional storage. Each of the components 152, 154, 158, and 160, are interconnected using various buses, and several of the components may be mounted on a common motherboard or in other manners as appropriate.

The processor 152 is configured to execute instructions within the end-point device(s) 140, including instructions stored in the memory 154, which in one embodiment includes the instructions of an application that may perform the functions disclosed herein, including certain logic, data processing, and data storing functions. The processor may be implemented as a chipset of chips that include separate and multiple analog and digital processors. The processor may be configured to provide, for example, for coordination of the other components of the end-point device(s) 140, such as control of user interfaces, applications run by end-point device(s) 140, and wireless communication by end-point device(s) 140.

The processor 152 may be configured to communicate with the user through control interface 164 and display interface 166 coupled to a display 156. The display 156 may be, for example, a TFT LCD (Thin-Film-Transistor Liquid Crystal Display) or an OLED (Organic Light Emitting Diode) display, or other appropriate display technology. The display interface 156 may include appropriate circuitry and configured for driving the display 156 to present graphical and other information to a user. The control interface 164 may receive commands from a user and convert them for submission to the processor 152. In addition, an external interface 168 may be provided in communication with processor 152, so as to enable near area communication of end-point device(s) 140 with other devices. External interface 168 may provide, for example, for wired communication in some implementations, or for wireless communication in other implementations, and multiple interfaces may also be used.

The memory 154 stores information within the end-point device(s) 140. The memory 154 can be implemented as one or more of a computer-readable medium or media, a volatile memory unit or units, or a non-volatile memory unit or units. Expansion memory may also be provided and connected to end-point device(s) 140 through an expansion interface (not shown), which may include, for example, a SIMM (Single In Line Memory Module) card interface. Such expansion memory may provide extra storage space for end-point device(s) 140 or may also store applications or other information therein. In some embodiments, expansion memory may include instructions to carry out or supplement the processes described above and may include secure information also. For example, expansion memory may be provided as a security module for end-point device(s) 140 and may be programmed with instructions that permit secure use of end-point device(s) 140. In addition, secure applications may be provided via the SIMM cards, along with additional information, such as placing identifying information on the SIMM card in a non-hackable manner.

The memory 154 may include, for example, flash memory and/or NVRAM memory. In one aspect, a computer program product is tangibly embodied in an information carrier. The computer program product contains instructions that, when executed, perform one or more methods, such as those described herein. The information carrier is a computer-or machine-readable medium, such as the memory 154, expansion memory, memory on processor 152, or a propagated signal that may be received, for example, over transceiver 160 or external interface 168.

In some embodiments, the user may use the end-point device(s) 140 to transmit and/or receive information or commands to and from the system 130 via the network 110. Any communication between the system 130 and the end-point device(s) 140 may be subject to an authentication protocol allowing the system 130 to maintain security by permitting only authenticated users (or processes) to access the protected resources of the system 130, which may include servers, databases, applications, and/or any of the components described herein. To this end, the system 130 may trigger an authentication subsystem that may require the user (or process) to provide authentication credentials to determine whether the user (or process) is eligible to access the protected resources. Once the authentication credentials are validated and the user (or process) is authenticated, the authentication subsystem may provide the user (or process) with permissioned access to the protected resources. Similarly, the end-point device(s) 140 may provide the system 130 (or other client devices) permissioned access to the protected resources of the end-point device(s) 140, which may include a GPS device, an image capturing component (e.g., camera), a microphone, and/or a speaker.

The end-point device(s) 140 may communicate with the system 130 through communication interface 158, which may include digital signal processing circuitry where necessary. Communication interface 158 may provide for communications under various modes or protocols, such as the Internet Protocol (IP) suite (commonly known as TCP/IP). Protocols in the IP suite define end-to-end data handling methods for everything from packetizing, addressing and routing, to receiving. Broken down into layers, the IP suite includes the link layer, containing communication methods for data that remains within a single network segment (link); the Internet layer, providing internetworking between independent networks; the transport layer, handling host-to-host communication; and the application layer, providing process-to-process data exchange for applications. Each layer contains a stack of protocols used for communications. In addition, the communication interface 158 may provide for communications under various telecommunications standards (2G, 3G, 4G, 5G, and/or the like) using their respective layered protocol stacks. These communications may occur through a transceiver 160, such as radio-frequency transceiver. In addition, short-range communication may occur, such as using a Bluetooth, Wi-Fi, or other such transceiver (not shown). In addition, GPS (Global Positioning System) receiver module 170 may provide additional navigation-and location-related wireless data to end-point device(s) 140, which may be used as appropriate by applications running thereon, and in some embodiments, one or more applications operating on the system 130.

The end-point device(s) 140 may also communicate audibly using audio codec 162, which may receive spoken information from a user and convert it to usable digital information. Audio codec 162 may likewise generate audible sound for a user, such as through a speaker, e.g., in a handset of end-point device(s) 140. Such sound may include sound from voice telephone calls, may include recorded sound (e.g., voice messages, music files, and/or the like) and may also include sound generated by one or more applications operating on the end-point device(s) 140, and in some embodiments, one or more applications operating on the system 130.

Various implementations of the distributed computing environment 100, including the system 130 and end-point device(s) 140, and techniques described here can be realized in digital electronic circuitry, integrated circuitry, specially designed ASICs (application specific integrated circuits), computer hardware, firmware, software, and/or combinations thereof.

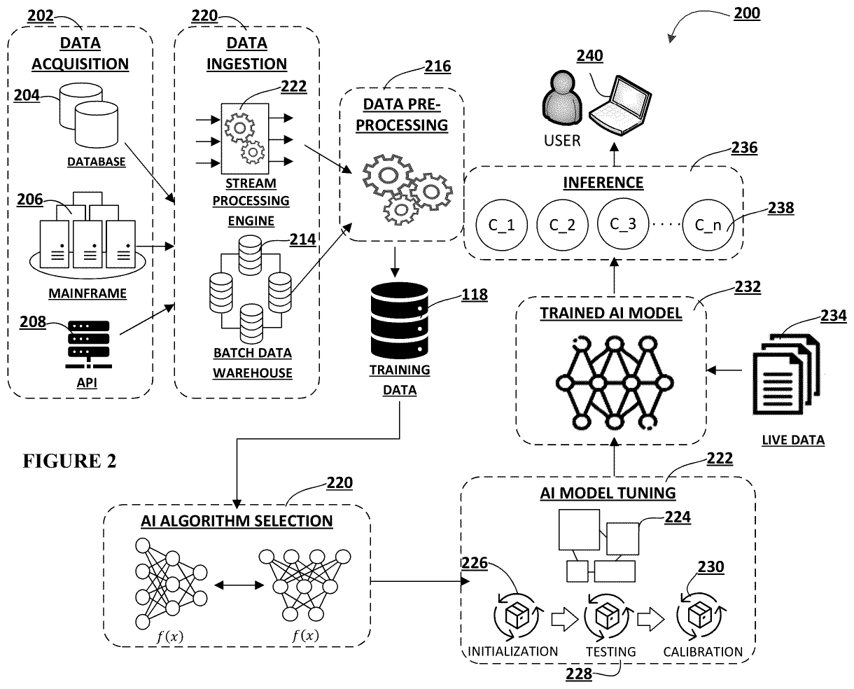

FIG. 2 illustrates an exemplary artificial intelligence (AI) engine subsystem architecture 200, in accordance with an embodiment of the disclosure. In some embodiments, the AI engine subsystem 200 may be included in a system (e.g., similar to the system 130 shown and described herein with respect to FIGS. 1A-1C, a dashboard generating system operatively coupled to a workflow engine and/or AI engine(s), and/or the like). Additionally, or alternatively, the AI engine subsystem 200 may be a subsystem of another system (e.g., similar to the system 130 shown and described herein with respect to FIGS. 1A-1C) that is in communication with a dashboard generating system operatively coupled to a workflow engine and/or AI engine(s) (e.g., via a network similar to the network 110 as shown and described herein with respect to FIGS. 1A-1C). The artificial intelligence subsystem 200 may include a data acquisition engine 202, data ingestion engine 210, data pre-processing engine 216, AI engine tuning engine 222, and inference engine 236.

The data acquisition engine 202 may identify various internal and/or external data sources to generate, test, and/or integrate new features for training the artificial intelligence engine 224. These internal and/or external data sources 204, 206, and 208 may be initial locations where the data originates or where physical information is first digitized. The data acquisition engine 202 may identify the location of the data and describe connection characteristics for access and retrieval of data. In some embodiments, data is transported from each data source 204, 206, or 208 using any applicable network protocols, such as the File Transfer Protocol (FTP), Hyper-Text Transfer Protocol (HTTP), or any of the myriad Application Programming Interfaces (APIs) provided by websites, networked applications, and other services. In some embodiments, the these data sources 204, 206, and 208 may include Enterprise Resource Planning (ERP) databases that host data related to day-to-day business activities such as accounting, procurement, project management, exposure management, supply chain operations, and/or the like, mainframe that is often the entity's central data processing center, edge devices that may be any piece of hardware, such as sensors, actuators, gadgets, appliances, or machines, that are programmed for certain applications and can transmit data over the internet or other networks, and/or the like. The data acquired by the data acquisition engine 202 from these data sources 204, 206, and 208 may then be transported to the data ingestion engine 210 for further processing.

Depending on the nature of the data imported from the data acquisition engine 202, the data ingestion engine 210 may move the data to a destination for storage or further analysis. Typically, the data imported from the data acquisition engine 202 may be in varying formats as they come from different sources, including RDBMS, other types of databases, S3 buckets, CSVs, or from streams. Since the data comes from different places, it needs to be cleansed and transformed so that it can be analyzed together with data from other sources. At the data ingestion engine 202, the data may be ingested in real-time, using the stream processing engine 212, in batches using the batch data warehouse 214, or a combination of both. The stream processing engine 212 may be used to process continuous data stream (e.g., data from edge devices), i.e., computing on data directly as it is received, and filter the incoming data to retain specific portions that are deemed useful by aggregating, analyzing, transforming, and ingesting the data. On the other hand, the batch data warehouse 214 collects and transfers data in batches according to scheduled intervals, trigger events, or any other logical ordering.

In artificial intelligence, the quality of data and the useful information that can be derived therefrom directly affects the ability of the artificial intelligence engine 224 to learn. The data pre-processing engine 216 may implement advanced integration and processing steps needed to prepare the data for artificial intelligence execution. This may include modules to perform any upfront, data transformation to consolidate the data into alternate forms by changing the value, structure, or format of the data using generalization, normalization, attribute selection, and aggregation, data cleaning by filling missing values, smoothing the noisy data, resolving the inconsistency, and removing outliers, and/or any other encoding steps as needed.

In addition to improving the quality of the data, the data pre-processing engine 216 may implement feature extraction and/or selection techniques to generate training data 218. Feature extraction and/or selection is a process of dimensionality reduction by which an initial set of data is reduced to more manageable groups for processing. A characteristic of these large data sets is a large number of variables that require a lot of computing resources to process. Feature extraction and/or selection may be used to select and /r combine variables into features, effectively reducing the amount of data that must be processed, while still accurately and completely describing the original data set. Depending on the type of artificial intelligence algorithm being used, this training data 218 may require further enrichment. For example, in supervised learning, the training data is enriched using one or more meaningful and informative labels to provide context so a artificial intelligence engine can learn from it. For example, labels might indicate whether a photo contains a bird or car, which words were uttered in an audio recording, or if an x-ray contains a tumor. Data labeling is required for a variety of use cases including computer vision, natural language processing, and speech recognition. In contrast, unsupervised learning uses unlabeled data to find patterns in the data, such as inferences or clustering of data points.

The AI tuning engine 222 may be used to train an artificial intelligence engine 224 using the training data 218 to make predictions or decisions without explicitly being programmed to do so. The artificial intelligence engine 224 represents what was learned by the selected artificial intelligence algorithm 220 and represents the rules, numbers, and any other algorithm-specific data structures required for classification. Selecting the right artificial intelligence algorithm may depend on a number of different factors, such as the problem statement and the kind of output needed, type and size of the data, the available computational time, number of features and observations in the data, and/or the like. Artificial intelligence algorithms may refer to programs (math and logic) that are configured to self-adjust and perform better as they are exposed to more data. To this extent, artificial intelligence algorithms are capable of adjusting their own parameters, given feedback on previous performance in making prediction about a dataset.

The artificial intelligence algorithms contemplated, described, and/or used herein include supervised learning (e.g., using logistic regression, using back propagation neural networks, using random forests, decision trees, and/or the like), unsupervised learning (e.g., using an Apriori algorithm, using K-means clustering), semi-supervised learning, reinforcement learning (e.g., using a Q-learning algorithm, using temporal difference learning), and/or any other suitable artificial intelligence engine type. Each of these types of artificial intelligence algorithms can implement any of one or more of a regression algorithm (e.g., ordinary least squares, logistic regression, stepwise regression, multivariate adaptive regression splines, locally estimated scatterplot smoothing, and/or the like), an instance-based method (e.g., k-nearest neighbor, learning vector quantization, self-organizing map, and/or the like), a regularization method (e.g., ridge regression, least absolute shrinkage and selection operator, elastic net, and/or the like), a decision tree learning method (e.g., classification and regression tree, iterative dichotomiser 3, C4.5, chi-squared automatic interaction detection, decision stump, random forest, multivariate adaptive regression splines, gradient boosting machines, and/or the like), a Bayesian method (e.g., naïve Bayes, averaged one-dependence estimators, Bayesian belief network, and/or the like), a kernel method (e.g., a support vector machine, a radial basis function, and/or the like), a clustering method (e.g., k-means clustering, expectation maximization, and/or the like), an associated rule learning algorithm (e.g., an Apriori algorithm, an Eclat algorithm, and/or the like), an artificial neural network model (e.g., a Perceptron method, a back-propagation method, a Hopfield network method, a self-organizing map method, a learning vector quantization method, and/or the like), a deep learning algorithm (e.g., a restricted Boltzmann machine, a deep belief network method, a convolution network method, a stacked auto-encoder method, and/or the like), a dimensionality reduction method (e.g., principal component analysis, partial least squares regression, Sammon mapping, multidimensional scaling, projection pursuit, and/or the like), an ensemble method (e.g., boosting, bootstrapped aggregation, AdaBoost, stacked generalization, gradient boosting machine method, random forest method, and/or the like), and/or the like.

To tune the artificial intelligence engine, the AI tuning engine 222 may repeatedly execute cycles of experimentation 226, testing 228, and tuning 230 to optimize the performance of the artificial intelligence algorithm 220 and refine the results in preparation for deployment of those results for consumption or decision making. To this end, the AI tuning engine 222 may dynamically vary hyperparameters each iteration (e.g., number of trees in a tree-based algorithm or the value of alpha in a linear algorithm), run the algorithm on the data again, then compare its performance on a validation set to determine which set of hyperparameters results in the most accurate model. The accuracy of the engine is the measurement used to determine which set of hyperparameters is best at identifying relationships and patterns between variables in a dataset based on the input, or training data 218. A fully trained artificial intelligence engine 232 is one whose hyperparameters are tuned and engine accuracy maximized.

The trained artificial intelligence engine 232, similar to any other software application output, can be persisted to storage, file, memory, or application, or looped back into the processing component to be reprocessed. More often, the trained artificial intelligence engine 232 is deployed into an existing production environment to make practical business decisions based on live data 234. To this end, the artificial intelligence subsystem 200 uses the inference engine 236 to make such decisions. The type of decision-making may depend upon the type of artificial intelligence algorithm used. For example, artificial intelligence engines trained using supervised learning algorithms may be used to structure computations in terms of categorized outputs (e.g., C_1, C_2 . . . C_n 238) or observations based on defined classifications, represent possible solutions to a decision based on certain conditions, model complex relationships between inputs and outputs to find patterns in data or capture a statistical structure among variables with unknown relationships, and/or the like. On the other hand, artificial intelligence engines trained using unsupervised learning algorithms may be used to group (e.g., C_1, C_2 . . . C_n 238) live data 234 based on how similar they are to one another to solve exploratory challenges where little is known about the data, provide a description or label (e.g., C_1, C_2 . . . C_n 238) to live data 234, such as in classification, and/or the like. These categorized outputs, groups (clusters), or labels are then presented to the user input system 130. In still other cases, artificial intelligence engines that perform regression techniques may use live data 234 to predict or forecast continuous outcomes.

It will be understood that the embodiment of the artificial intelligence subsystem 200 illustrated in FIG. 2 is exemplary and that other embodiments may vary. As another example, in some embodiments, the artificial intelligence subsystem 200 may include more, fewer, or different components.

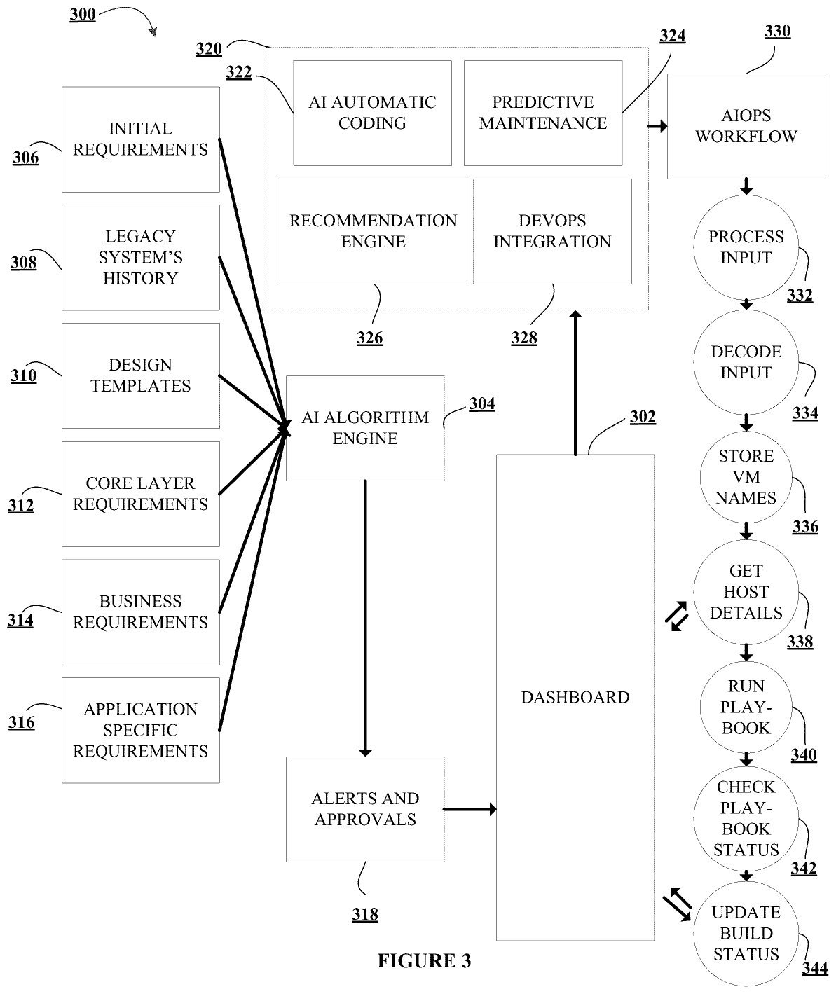

FIG. 3 illustrates a flowchart 300 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of a process flow in accordance with the flowchart 300. For example, a dashboard generating system operatively coupled to a workflow engine and/or AI engine(s) (e.g., the system 130 described herein with respect to FIG. 1A-1C) may perform one or more of the steps of a process flow in accordance with the flowchart 300. In some embodiments, an artificial intelligence engine (e.g., such as the AI engine shown in FIG. 2) may perform one or more of the steps of a process flow in accordance with the flowchart 300.

In some embodiments, the flowchart 300 may include a dashboard 302, an AI algorithm engine 304, and/or a generative AI model 320. In some embodiments, the dashboard 302 may be operatively coupled to a workflow engine configured to receive input from the dashboard 302, analyze the input, transmit notifications associated with the input, and/or transmit the input to networked devices. Further, the dashboard 302 may be in communication with the AI algorithm engine 304 and/or the generative AI model 320.

In some embodiments, the AI algorithm engine 304 may receive a plurality of inputs related to architectural requirements for a system build from a plurality of locations and/or user devices. For example, the AI algorithm engine 304 may receive inputs in the form initial requirements 306, legacy system's history 308, design templates 310, core layer requirements 312, business requirements 314, application specific requirements 316, and/or the like. Further, the AI algorithm engine 304 may be configured to analyze the inputs and compile and/or reformat the inputs into a file including a plurality of architectural requirements. Additionally, and/or alternatively, the file may be transmitted with an alert for manual approval 318 of the architectural requirements prior to being transferred to the dashboard 302.

In some embodiments, the generative AI model 320 may include a plurality of functions including AI automatic coding 322, predictive maintenance 324, recommendation engine 326, and/or DevOps integration 328. In such embodiments, the generative AI model 320, when performing AI automatic coding 322, may be configured to receive an input file of parameters for a system build. Further, the generative AI model 320 may extract the parameters for the system build and generate code to construct the system build following the parameters. Additionally, and/or, alternatively, the generative AI model 320, when performing the predictive maintenance 324, may be configured to analyze data associated with the system build and identify problems by flagging the problems for adjustment. In some embodiments, the generative AI model 320, when serving as the recommendation engine 326, may be configured to provide system build change recommendations based on predictive analytics and/or historical data. Additionally, and/or alternatively, the generative AI model 320 may be configured for DevOps integration 328 to streamline the implementation of system build changes.

In some embodiments, the generative AI model 320 may be configured to perform an AIOps workflow 330. In such embodiments, the AIOps workflow 330 may begin with step 332, where the generative AI model 320 will first process input to the generative AI model 320. Further, the AIOps workflow 330 may include a step 334, where the generative AI model 320 may be configured to decode parameters from the input. Additionally, and/or alternatively, the AIOps workflow 330 may include a step 336, where the generative AI model 320 may be configured to store virtual machine (VM) names in a configuration storage. In some embodiments, the AIOps workflow 330 may include a step 338, where the generative AI model 320 may be configured to request and receive additional parameters for the system build as needed. In such embodiments, the generative AI model 320 may communicate with the dashboard 302 for the additional parameters. Further, the AIOps workflow 330 may include a step 340, where the generative AI model 320 may be configured to run a generated playbook. Additionally, and/or alternatively, the AIOps workflow 330 may include a step 342, where the generative AI model 320 may be configured to check the status of the generated playbook as the playbook is running. In some embodiments, the AIOps workflow 330 may include a step 344, where the generative AI model 320 may be configured to update the system build status. In such embodiments, the generative AI model 320 may communicate with the dashboard 302 regarding updates to the system build status.

The flowchart 300 may include additional embodiments, such as any single embodiment or any combination of embodiments described herein. Although FIG. 3 shows example elements of the flowchart 300, in some embodiments, the flowchart 300 may include additional elements, fewer elements, different elements, or differently arranged elements than those depicted in FIG. 3. Additionally, or alternatively, two or more of the elements of the process flow 300 may operate in parallel.

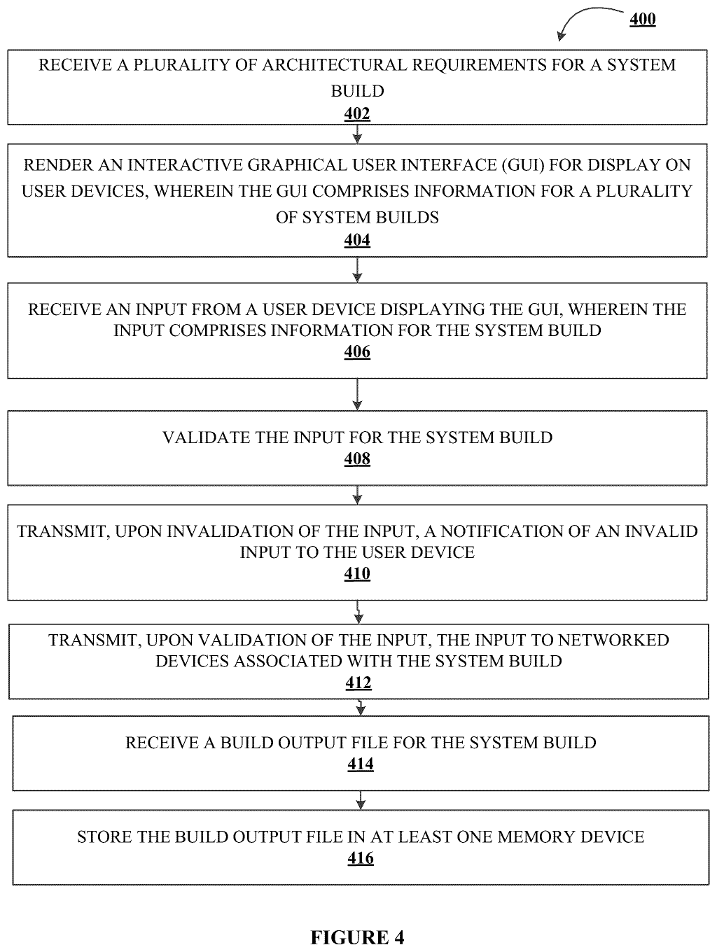

FIG. 4 illustrates a process flow 400 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of process flow 400. For example, a dashboard generating system operatively coupled to a workflow engine and/or AI engine(s) (e.g., the system 130 described herein with respect to FIG. 1A-1C) may perform one or more of the steps of process flow 400. In some embodiments, an artificial intelligence engine (e.g., such as the AI engine shown in FIG. 2) may perform one or more of the steps of process flow 400.

As shown in block 402, the process flow 400 may include the step of receiving a plurality of architectural requirements for a system build. In some embodiments, the system build (e.g., the design of a server, computer system, and/or the like) may include design, structure, and/or build constraints that may need to be incorporated and/or considered in the system build. Further, the plurality of architectural requirements (e.g., initial requirements, legacy system's history, design templates, core layer requirements, business requirements, application specific requirements, and/or the like) may be received from an AI model (e.g., the AI algorithm engine 304 as shown and described herein with respect to FIG. 3).

As shown in block 404, the process flow 400 may include the step of rendering an interactive graphical user interface (GUI) for display on user devices, where the GUI includes information for a plurality of system builds. In some embodiments, the GUI may include text boxes, drop-down menus, buttons, sliders, on/off toggles, widgets, hyperlinks, files, and/or the like. Further, the GUI may be configured to receive data from user devices and/or transmit data to user devices.

As shown in block 406, the process flow 400 may include the step of receiving an input from a user device displaying the GUI, where the input includes information for the system build. In some embodiments, the user device displaying the GUI may transmit an input (e.g., a file, an email, text, and/or the like) to the system. In such embodiments, the input may be stored temporarily and/or permanently by the system. Further, the system may be configured to analyze the input.

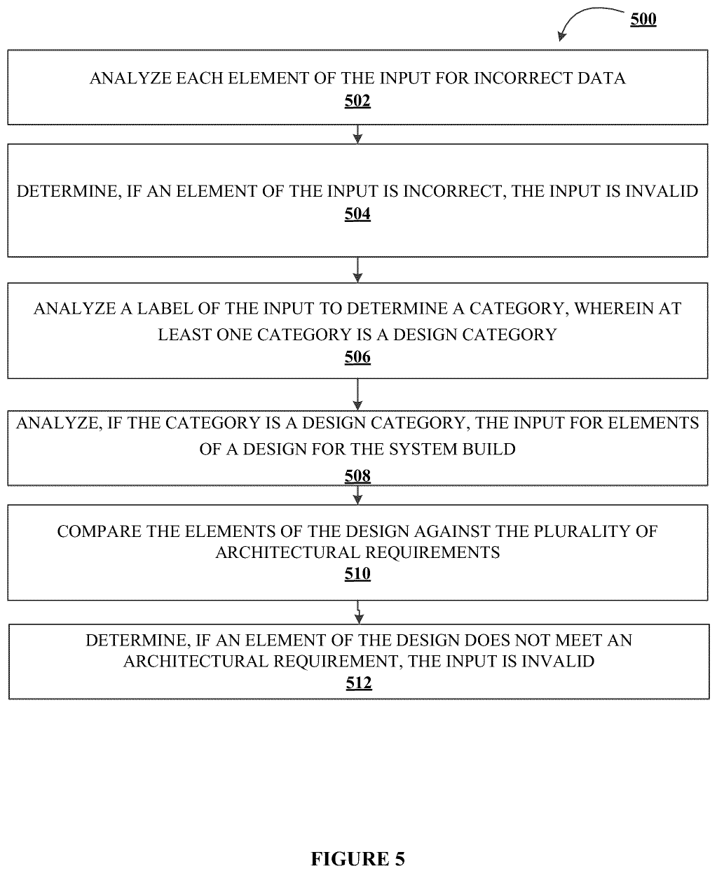

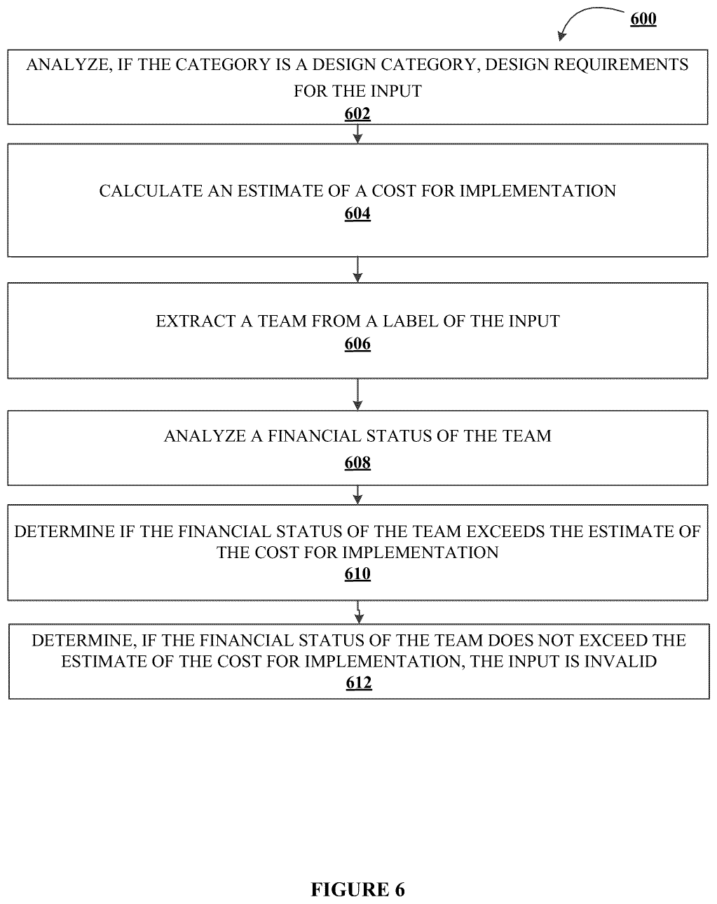

As shown in block 408, the process flow 400 may include the step of validating the input for the system build. In some embodiments, an AI model may receive the input for the system build. Further, the AI model may be configured to analyze the input for any invalid data (e.g., typographical errors, noncompliant data, invalid financial data, and/or the like). Additionally, and/or alternatively, the step of block 408 may be performed by some and/or all of the steps of the process flows 500 and 600 as shown and described herein with respect to FIGS. 5 and 6.

As shown in block 410, the process flow 400 may include the step of transmitting, upon invalidation of the input, a notification of an invalid input to the user device. In some embodiments, the AI model may determine the input and/or an element of the input meets a criterion for invalidation. In such embodiments, the AI model may transmit a notification (e.g., a text message, email, alert, an image on the GUI, and/or the like) that the input is invalid to a user of the user device. Further, the notification may include information regarding what criterion for invalidation the input met and/or request the user to adjust the input to correct the invalidity and to resubmit the input.

As shown in block 412, the process flow 400 may include the step of transmitting, upon validation of the input, the input to networked devices associated with the system build. In some embodiments, the AI model may determine the input and/or an element of the input does not meet a criterion for invalidation. In such embodiments, the AI model may transmit a notification (e.g., a text message, email, alert, display on the GUI, and/or the like) that the input is valid to a user of the user device. Further, the AI model may be configured to transmit the input to devices and/or locations requested by the user of the user device.

As shown in block 414, the process flow 400 may include the step of receiving a build output file for the system build. In some embodiments, the build output file (e.g., a file containing compiled computer code for a system build) may be transmitted by a generative AI model (e.g., the generative AI model 320 as shown and described herein with respect to FIG. 3). Further, the build output file may be a file for a new build or an update to an existing build.

As shown in block 416, the process flow 400 may include the step of storing the build output file in at least one memory device. In some embodiments, the build output file may be stored temporarily and/or permanently in the at least one memory device. Further, the build output file may be accessed by a plurality of networked devices. Additionally, or alternatively, the build output file may be used to setup a new system build in accordance with the build output file. In some embodiments, the build output file may be configured to receive updates and/or be overwritten by a new version of the build output file.

The process flow 400 may include additional embodiments, such as any single embodiment or any combination of embodiments described herein. Although FIG. 4 shows example blocks of the process flow 400, in some embodiments, the process flow 400 may include additional blocks, fewer blocks, different blocks, or differently arranged blocks than those depicted in FIG. 4. Additionally, or alternatively, two or more of the blocks of the process flow 400 may be performed in parallel.

FIG. 5 illustrates a process flow 500 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of process flow 500. For example, a dashboard generating system operatively coupled to a workflow engine and/or AI engine(s) (e.g., the system 130 described herein with respect to FIG. 1A-1C) may perform one or more of the steps of process flow 500. In some embodiments, an artificial intelligence engine (e.g., such as the AI engine shown in FIG. 2) may perform one or more of the steps of process flow 500.

In some embodiments, and as shown in block 502, the process flow 500 may include the step of analyzing each element of the input for incorrect data. In some embodiments, the system may include an AI and/or ML model (e.g., an NLP model, LLM, big data model, and/or the like) configured to analyze input to the system from user devices. Further, the analysis of the AI and/or ML model may include a determination of invalidity of an element of the input (e.g., typographical errors, nonexistent build names, noncompliant data, invalid financial data, and/or the like). Additionally, and/or alternatively, the analysis by the AI and/or ML model may include extracting an element of the input, determining what the element of the input is directed to (e.g., is the element of the input a build name, a group name, a category label, computer code, hardware specifications, and/or the like), comparing the element of the input against data stored in the system, calculating a percent chance of invalidity, and/or comparing the percent chance against a threshold.

In some embodiments, and as shown in block 504, the process flow 500 may include the step of determining, if an element of the input is incorrect, the input is invalid. In some embodiments, if at least one element of the input has a percent chance of invalidity higher than the threshold, the system may determine the input is invalid. Additionally, and/or alternatively, if at least one element of the input has a percent chance of invalidity lower than the threshold, the system may determine the input is invalid. In some embodiments, the step of block 504 may be followed by the step 410 as shown and described herein with respect to FIG. 4.

In some embodiments, and as shown in block 506, the process flow 500 may include the step of analyzing a label of the input to determine a category, where at least one category is a design category. In some embodiments, an input from a user device may be categorized fully and/or partially by a label (e.g., a set of information used to categorize the input) associated with the input. In such embodiments, the label may include information regarding a category the input is for. For example, a user may submit an input in the form of an email including an inquiry about the status of a design for a system build. The email may have an associated label that includes a design category. In such embodiments, the AI and/or ML model may be configured to analyze the email and extract the design category from the email to determine the category of the email is the design category.

In some embodiments, and as shown in block 508, the process flow 500 may include the step of analyzing, if the category is a design category, the input for elements of a design for the system build. In some embodiments, upon determination the input is in regard to a design, the AI and/or ML model may analyze each element of the input. Further, the analysis may include extracting an element of the input and/or determining if the element of the input is directed to the design of the system build. Additionally, or alternatively, the AI and/or ML model may be configured to group related elements of the input together in the analysis to determine if the grouped related elements are directed to the design for the system build.

In some embodiments, and as shown in block 510, the process flow 500 may include the step of comparing the elements of the design against the plurality of architectural requirements. In some embodiments, the AI and/or ML model may be configured to review the plurality of architectural requirements generated by an AI model (e.g., the AI algorithm engine 304 as shown and described herein with respect to FIG. 3). Further the AI and/or ML model may be configured to, for each element and/or grouped related elements of the input determined to be directed to the design of the system build, compare (e.g., review an element to check if it violates an architectural requirement of the plurality of architectural requirements) an element and/or group of related elements of the input determined to be directed to the design of the system build against the plurality of architectural requirements.

In some embodiments, and as shown in block 512, the process flow 500 may include the step of determining, if an element of the design does not meet an architectural requirement, the input is invalid. In some embodiments, the AI and/or ML model may analyze an element of the design against the plurality of architectural requirements. Further, the analysis by the AI and/or ML model may include extracting the element of the design, determining what requirement the element is most related to, comparing the element of the input to the requirement, calculating a percent chance of violation, and/or comparing the percent chance against a threshold. In such embodiments, if the percent chance exceeds the threshold, the AI and/or ML model may determine the input is invalid.

The process flow 500 may include additional embodiments, such as any single embodiment or any combination of embodiments described herein. Although FIG. 5 shows example blocks of the process flow 500, in some embodiments, the process flow 500 may include additional blocks, fewer blocks, different blocks, or differently arranged blocks than those depicted in FIG. 5. Additionally, or alternatively, two or more of the blocks of the process flow 500 may be performed in parallel.

FIG. 6 illustrates a process flow 600 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of process flow 600. For example, a dashboard generating system operatively coupled to a workflow engine and/or AI engine(s) (e.g., the system 130 described herein with respect to FIG. 1A-1C) may perform one or more of the steps of process flow 600. In some embodiments, an artificial intelligence engine (e.g., such as the AI engine shown in FIG. 2) may perform one or more of the steps of process flow 600.

In some embodiments, and as shown in block 602, the process flow 600 may include the step of analyzing, if the category is a design category, design requirements for the input. In some embodiments, an input may include a team requesting a new system build and/or an update to an existing system build. In such embodiments, an AI and/or ML model (e.g., the AI and/or ML model as shown and described herein with respect to FIG. 5) may be configured to extract each design requirement for the system build in the input.

In some embodiments, and as shown in block 604, the process flow 600 may include the step of calculating an estimate of a cost for implementation. In some embodiments, the AI and/or ML model may be configured to generate a cost estimate for each design requirement and sum each cost estimate into the cost for implementation (e.g., how much money it will require to create the system build). For example, a system build may require base hardware, memory allocation, implementation time, and/or the like that each add a cost to the cost for implementation of the system build. In such embodiments, the AI and/or ML model may be configured to take an individual need, analyze the individual need (e.g., based on historical data and/or other parameters generate a cost for the individual need), and determine a cost for the individual need.

In some embodiments, and as shown in block 606, the process flow 600 may include the step of extracting a team from a label of the input. In some embodiments, an input from a user device may be categorized fully and/or partially by a label (e.g., a set of information used to categorize the input) associated with the input. In such embodiments, the label may include information regarding the team the input is associated with. For example, a user may submit an input in the form of an email including a new design for a system build. The email may have an associated label that includes the team the user is associated with. In such embodiments, the AI and/or ML model may be configured to analyze the email and extract the label to determine the team the user is associated with.

In some embodiments, and as shown in block 608, the process flow 600 may include the step of analyzing a financial status of the team. In some embodiments, the dashboard may store a plurality of data related to the financial status of the team. Further, the AI and/or ML model may extract the plurality of data related to the financial status of the team (e.g., via an API with a financial system, from a database, and/or the like). Additionally, and/or alternatively, the AI and/or ML model may analyze the plurality of data to determine the financial status of the team (e.g., the amount of money the team has available, the amount of money the team generates on a temporal basis, the amount of money the team spends on a temporal basis, and/or the like). In such embodiments, the determination of the financial status of the team may include an estimate of the money available to the team.

In some embodiments, and as shown in block 610, the process flow 600 may include the step of determining if the financial status of the team exceeds the estimate of the cost for implementation. In some embodiments, the AI and/or ML model may compare the estimate of the money available to the team against the estimate of the cost of implementation. In such embodiments, the AI and/or ML model may be configured to evaluate if the estimate of the money available to the team is higher than the estimate of the cost of implementation.

In some embodiments, and as shown in block 612, the process flow 600 may include the step of determining, if the financial status of the team does not exceed the estimate of the cost for implementation, the input is invalid. In some embodiments, if the estimate of the money available to the team is below the estimate of the cost of implementation, the AI and/or ML model may determine the input is invalid. Further, if the AI and/or ML model determines the input is invalid, the step of block 612 may be followed by the step of block 410 as shown and described herein with respect to FIG. 4.

The process flow 600 may include additional embodiments, such as any single embodiment or any combination of embodiments described herein. Although FIG. 6 shows example blocks of the process flow 600, in some embodiments, the process flow 600 may include additional blocks, fewer blocks, different blocks, or differently arranged blocks than those depicted in FIG. 6. Additionally, or alternatively, two or more of the blocks of the process flow 600 may be performed in parallel.

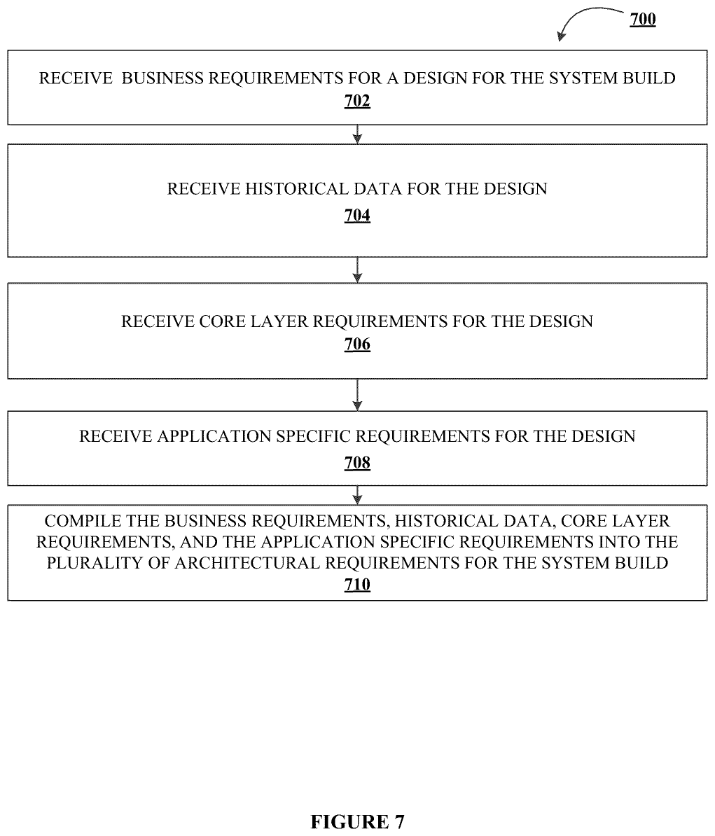

FIG. 7 illustrates a process flow 700 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of process flow 700. For example, a dashboard generating system operatively coupled to a workflow engine and/or AI engine(s) (e.g., the system 130 described herein with respect to FIG. 1A-1C) may perform one or more of the steps of process flow 700. In some embodiments, an artificial intelligence engine (e.g., such as the AI engine shown in FIG. 2) may perform one or more of the steps of process flow 700.

In some embodiments, and as shown in block 702, the process flow 700 may include the step of receiving business requirements for a design for the system build. In some embodiments, an AI model (e.g., the AI algorithm engine 304 as shown and described herein with respect to FIG. 3) may be configured to receive a plurality of architectural requirements for the design for the system build. Further, the plurality of architectural requirements may be received from a plurality of users, locations, and/or networked devices. In some embodiments, the plurality of architectural requirements may include business requirements (e.g., initial requirements from the team requesting the design, requirements specific to the line of business, and/or the like) for the design of the system build.

In some embodiments, and as shown in block 704, the process flow 700 may include the step of receiving historical data for the design. In some embodiments, the plurality of architectural requirements may include historical data (e.g., positives of a legacy system build, negatives of a legacy system build, and/or the like) for the design of the system build.

In some embodiments, and as shown in block 706, the process flow 700 may include the step of receiving core layer requirements for the design. In some embodiments, the plurality of architectural requirements may include core layer requirements (e.g., system resiliency, system uptime, anti-affinity, channel segregation, and/or the like) for the design of the system build.

In some embodiments, and as shown in block 708, the process flow 700 may include the step of receiving application specific requirements for the design. In some embodiments, the plurality of architectural requirements may include application specific requirements (e.g., requirements requested by the team requesting the design) for the design of the system build.

In some embodiments, and as shown in block 710, the process flow 700 may include the step of compiling the business requirements, historical data, core layer requirements, and the application specific requirements into the plurality of architectural requirements for the system build. In some embodiments, the requirements may be received by the AI model from a plurality of users, locations, and/or networked devices. Further, the requirements may be transmitted to the AI model in a plurality of files. Additionally, or alternatively, a requirement from a location may overlap with a requirement from another location. In some embodiments, the AI model may analyze each file of requirements and compile each unique requirement into a single file including the plurality of architectural requirements.

The process flow 700 may include additional embodiments, such as any single embodiment or any combination of embodiments described herein. Although FIG. 7 shows example blocks of the process flow 700, in some embodiments, the process flow 700 may include additional blocks, fewer blocks, different blocks, or differently arranged blocks than those depicted in FIG. 7. Additionally, or alternatively, two or more of the blocks of the process flow 700 may be performed in parallel.

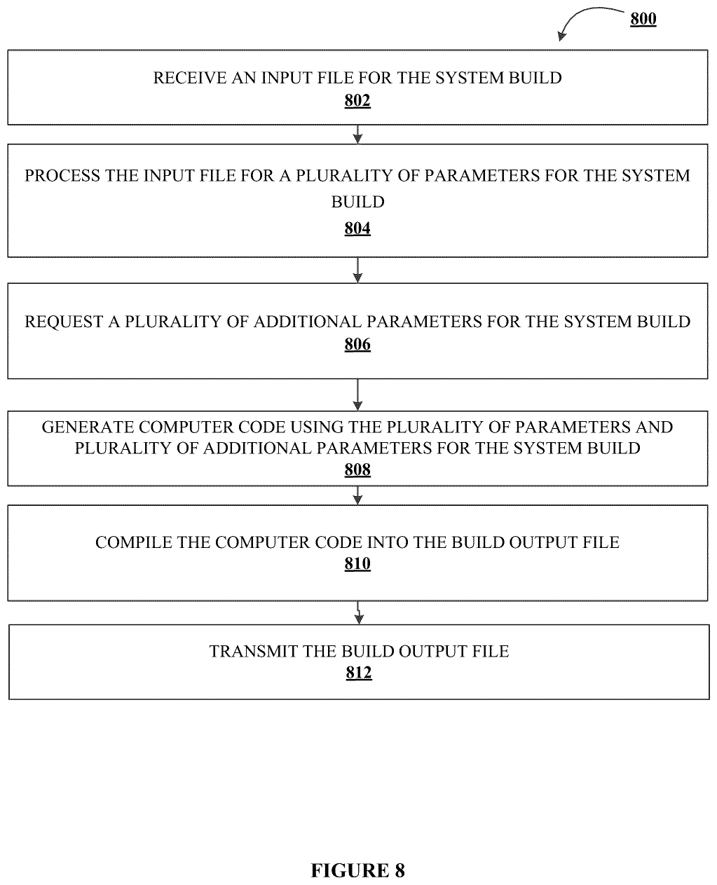

FIG. 8 illustrates a process flow 800 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of process flow 800. For example, a dashboard generating system operatively coupled to a workflow engine and/or AI engine(s) (e.g., the system 130 described herein with respect to FIG. 1A-1C) may perform one or more of the steps of process flow 800. In some embodiments, an artificial intelligence engine (e.g., such as the AI engine shown in FIG. 2) may perform one or more of the steps of process flow 800.

In some embodiments, and as shown in block 802, the process flow 800 may include the step of receiving an input file for the system build. In some embodiments, a generative AI model (e.g., the generative AI model 320 as shown and described herein with respect to FIG. 3) may be configured to generate code for system builds. In such embodiments, the generative AI model may receive an input file that includes data and/or parameters related to a design for a system build.

In some embodiments, and as shown in block 804, the process flow 800 may include the step of processing the input file for a plurality of parameters for the system build. In some embodiments, upon receipt of an input file, the generative AI model may scan the file for data elements that may be parameters for a system build. Further, upon detection of a data element that may be a parameter for a system build, the generative AI may be configured to extract the data element and/or store the data element for later use. Additionally, and/or alternatively, the generative AI may continue scanning the file until each data element of the file has been scanned.

In some embodiments, and as shown in block 806, the process flow 800 may include the step of requesting a plurality of additional parameters for the system build. In some embodiments, the generative AI model may need a plurality of additional parameters to generate code related to a system build. Further, the generative AI model may analyze the extracted data elements and/or parameters from the input file. Additionally, and/or alternatively, the generative AI model may determine additional parameters are necessary for the system build. In such embodiments, the generative AI model may send a request (e.g., to the dashboard 302 as shown and described herein with respect to FIG. 3) for the plurality of additional parameters.

In some embodiments, and as shown in block 808, the process flow 800 may include the step of generating computer code using the plurality of parameters and plurality of additional parameters for the system build. In some embodiments, once the generative AI model has received all necessary parameters, the generative AI model may begin generating computer code to construct the system build on top of the necessary hardware for the system build.

In some embodiments, and as shown in block 810, the process flow 800 may include the step of compiling the computer code into the build output file. In some embodiments, the generated computer code may be in a plurality of files, may be a plurality of file types, and/or may include a large file size. In such embodiments, the generative AI model, prior to transmitting the computer code, may be configured to compile, compress, and/or reformat the computer code into a single build output file.

In some embodiments, and as shown in block 812, the process flow 800 may include the step of transmitting the build output file. In some embodiments, upon successful compilation of the generated computer code into a build output file, the generative AI may be configured to transmit the build output file for storage, review, and/or further use. Further, the generative AI model may transmit the build output file to a dashboard (e.g., the dashboard 302 as shown and described herein with respect to FIG. 3). In some embodiments, the generative AI model may generate code for a system build by following some and/or all of the steps of the AIOps workflow 330 as shown and described herein with respect to FIG. 3.

The process flow 800 may include additional embodiments, such as any single embodiment or any combination of embodiments described herein. Although FIG. 8 shows example blocks of the process flow 800, in some embodiments, the process flow 800 may include additional blocks, fewer blocks, different blocks, or differently arranged blocks than those depicted in FIG. 8. Additionally, or alternatively, two or more of the blocks of the process flow 800 may be performed in parallel.

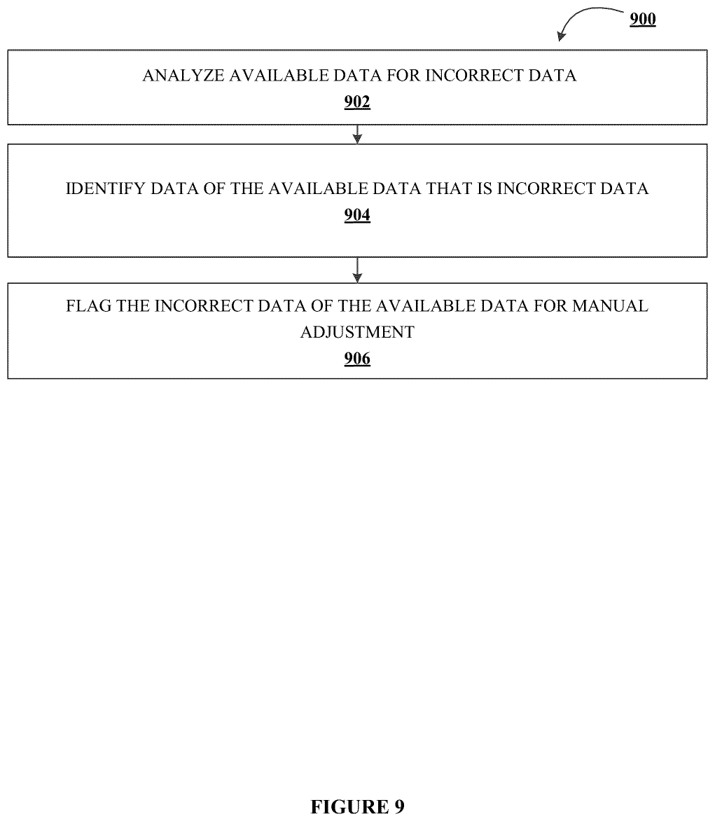

FIG. 9 illustrates a process flow 900 for automatic requirements capture and generation of system builds using artificial intelligence, in accordance with an embodiment of the invention. In some embodiments, a system (e.g., similar to one or more of the systems described herein with respect to FIGS. 1A-1C) may perform one or more of the steps of process flow 900. For example, a dashboard generating system operatively coupled to a workflow engine and/or AI engine(s) (e.g., the system 130 described herein with respect to FIG. 1A-1C) may perform one or more of the steps of process flow 900. In some embodiments, an artificial intelligence engine (e.g., such as the AI engine shown in FIG. 2) may perform one or more of the steps of process flow 900.

In some embodiments, and as shown in block 902, the process flow 900 may include the step of analyzing available data for incorrect data. In some embodiments, a generative AI model (e.g., the generative AI model 320 as shown and described herein with respect to FIG. 3) may be configured to perform predictive maintenance and/or cleanup for a system build. For example, a system build may include available data that may include data of the available data that may be incorrect. In such embodiments, the generative AI model may extract, review, and/or compare an element of the available data to determine if the element of the available data may be incorrect data.

In some embodiments, and as shown in block 904, the process flow 900 may include the step of identifying data of the available data that is incorrect data. In some embodiments, the analysis of the generative AI model may determine at least one element of the available data is incorrect data. Further, the generative AI model may be configured to store a location of the identified data of the available data that is incorrect data.

In some embodiments, and as shown in block 906, the process flow 900 may include the step of flagging the incorrect data of the available data for manual adjustment. In some embodiments, the generative AI model may be configured to generate a notice including each element of the available data that is incorrect data, the location of each element of the available data that is incorrect data, and/or recommendations on how to adjust each element of the available data that is incorrect data. Further, the notice may be transmitted to a user associated with the system build and/or updating the data associated with the system build.

The process flow 900 may include additional embodiments, such as any single embodiment or any combination of embodiments described herein. Although FIG. 9 shows example blocks of the process flow 900, in some embodiments, the process flow 900 may include additional blocks, fewer blocks, different blocks, or differently arranged blocks than those depicted in FIG. 9. Additionally, or alternatively, two or more of the blocks of the process flow 900 may be performed in parallel.

As will be appreciated by one of ordinary skill in the art, the present invention may be embodied as an apparatus (including, for example, a system, a machine, a device, a computer program product, and/or the like), as a method (including, for example, a business process, a computer-implemented process, and/or the like), or as any combination of the foregoing. Accordingly, embodiments of the present invention may take the form of an entirely software embodiment (including firmware, resident software, micro-code, and the like), an entirely hardware embodiment, or an embodiment combining software and hardware aspects that may generally be referred to herein as a “system.” Furthermore, embodiments of the present invention may take the form of a computer program product that includes a computer-readable storage medium having computer-executable program code portions stored therein. As used herein, a processor may be “configured to” perform a certain function in a variety of ways, including, for example, by having one or more special-purpose circuits perform the functions by executing one or more computer-executable program code portions embodied in a computer-readable medium, and/or having one or more application-specific circuits perform the function.

It will be understood that any suitable computer-readable medium may be utilized. The computer-readable medium may include, but is not limited to, a non-transitory computer-readable medium, such as a tangible electronic, magnetic, optical, infrared, electromagnetic, and/or semiconductor system, apparatus, and/or device. For example, in some embodiments, the non-transitory computer-readable medium includes a tangible medium such as a portable computer diskette, a hard disk, a random-access memory (RAM), a read-only memory (ROM), an erasable programmable read-only memory (EPROM or Flash memory), a compact disc read-only memory (CD-ROM), and/or some other tangible optical and/or magnetic storage device. In other embodiments of the present invention, however, the computer-readable medium may be transitory, such as a propagation signal including computer-executable program code portions embodied therein.

It will also be understood that one or more computer-executable program code portions for carrying out the specialized operations of the present invention may be required on the specialized computer include object-oriented, scripted, and/or unscripted programming languages, such as, for example, Java, Perl, Smalltalk, C++, SAS, SQL, Python, Objective C, and/or the like. In some embodiments, the one or more computer-executable program code portions for carrying out operations of embodiments of the present invention are written in conventional procedural programming languages, such as the “C” programming languages and/or similar programming languages. The computer program code may alternatively or additionally be written in one or more multi-paradigm programming languages, such as, for example, F#.

It will further be understood that some embodiments of the present invention are described herein with reference to flowchart illustrations and/or block diagrams of systems, methods, and/or computer program products. It will be understood that each block included in the flowchart illustrations and/or block diagrams, and combinations of blocks included in the flowchart illustrations and/or block diagrams, may be implemented by one or more computer-executable program code portions. These computer-executable program code portions execute via the processor of the computer and/or other programmable data processing apparatus and create mechanisms for implementing the steps and/or functions represented by the flowchart(s) and/or block diagram block(s).

It will also be understood that the one or more computer-executable program code portions may be stored in a transitory or non-transitory computer-readable medium (e.g., a memory, and the like) that can direct a computer and/or other programmable data processing apparatus to function in a particular manner, such that the computer-executable program code portions stored in the computer-readable medium produce an article of manufacture, including instruction mechanisms which implement the steps and/or functions specified in the flowchart(s) and/or block diagram block(s).

The one or more computer-executable program code portions may also be loaded onto a computer and/or other programmable data processing apparatus to cause a series of operational steps to be performed on the computer and/or other programmable apparatus. In some embodiments, this produces a computer-implemented process such that the one or more computer-executable program code portions which execute on the computer and/or other programmable apparatus provide operational steps to implement the steps specified in the flowchart(s) and/or the functions specified in the block diagram block(s). Alternatively, computer-implemented steps may be combined with operator and/or human-implemented steps in order to carry out an embodiment of the present invention.

While certain exemplary embodiments have been described and shown in the accompanying drawings, it is to be understood that such embodiments are merely illustrative of, and not restrictive on, the broad invention, and that this invention not be limited to the specific constructions and arrangements shown and described, since various other changes, combinations, omissions, modifications and substitutions, in addition to those set forth in the above paragraphs, are possible. Those skilled in the art will appreciate that various adaptations and modifications of the just described embodiments can be configured without departing from the scope and spirit of the invention. Therefore, it is to be understood that, within the scope of the appended claims, the invention may be practiced other than as specifically described herein.

What is claimed is:

1. A system for automatic requirements capture and generation of system builds using artificial intelligence, the system comprising:
at least one memory device with computer-readable program code stored thereon;
at least one processing device operatively coupled to the at least one memory device, wherein executing the computer-readable code is configured to cause the at least one processing device to:
receive a plurality of architectural requirements for a system build;
render an interactive graphical user interface (GUI) for display on user devices, wherein the GUI comprises information for a plurality of system builds;
receive an input from a user device displaying the GUI, wherein the input comprises information for the system build;
validate the input for the system build;
transmit, upon invalidation of the input, a notification of an invalid input to the user device;
transmit, upon validation of the input, the input to networked devices associated with the system build;
receive a build output file for the system build; and
store the build output file in the at least one memory device.

2. The system of claim 1, wherein validating the input comprises using an AI model configured to:
analyze each element of the input for incorrect data;
determine, if an element of the input is incorrect, the input is invalid;
analyze a label of the input to determine a category, wherein at least one category is a design category;
analyze, if the category is a design category, the input for elements of a design for the system build;
compare the elements of the design against the plurality of architectural requirements; and
determine, if an element of the design does not meet an architectural requirement, the input is invalid.

3. The system of claim 2, wherein the AI model is configured to:
analyze, if the category is a design category, design requirements for the input;
calculate an estimate of a cost for implementation;
extract a team from a label of the input;
analyze a financial status of the team;
determine if the financial status of the team exceeds the estimate of the cost for implementation; and
determine, if the financial status of the team does not exceed the estimate of the cost for implementation, the input is invalid.

4. The system of claim 1, comprising an AI engine configured to:
receive business requirements for a design for the system build;
receive historical data for the design;
receive core layer requirements for the design;
receive application specific requirements for the design; and
compile the business requirements, historical data, core layer requirements, and the application specific requirements into the plurality of architectural requirements for the system build.

5. The system of claim 1, comprising a generative AI tool configured to:
receive an input file for the system build;
process the input file for a plurality of parameters for the system build;
request a plurality of additional parameters for the system build;
generate computer code using the plurality of parameters and plurality of additional parameters for the system build;
compile the computer code into the build output file; and
transmit the build output file.

6. The system of claim 5, wherein the generative AI tool is integrated with at least one configuration management tool.

7. The system of claim 6, wherein the generative AI is configured to:
analyze available data for incorrect data;
identify data of the available data that is incorrect data; and
flag the incorrect data of the available data for manual adjustment.

8. A computer program product for automatic requirements capture and generation of system builds using artificial intelligence, the computer program product comprising a non-transitory computer-readable medium comprising code causing an apparatus to:
receive a plurality of architectural requirements for a system build;
render an interactive graphical user interface (GUI) for display on user devices, wherein the GUI comprises information for a plurality of system builds;
receive an input from a user device displaying the GUI, wherein the input comprises information for the system build;
validate the input for the system build;
transmit, upon invalidation of the input, a notification of an invalid input to the user device;
transmit, upon validation of the input, the input to networked devices associated with the system build;
receive a build output file for the system build; and
store the build output file in at least one memory device.

9. The computer program product of claim 8, wherein validating the input comprises an AI model configured to:
analyze each element of the input for incorrect data;
determine, if an element of the input is incorrect, the input is invalid;
analyze a label of the input to determine a category, wherein at least one category is a design category;
analyze, if the category is a design category, the input for elements of a design for the system build;
compare the elements of the design against the plurality of architectural requirements; and
determine, if an element of the design does not meet an architectural requirement, the input is invalid.

10. The computer program product of claim 9, wherein the AI model is configured to:
analyze, if the category is a design category, design requirements for the input;
calculate an estimate of a cost for implementation;
extract a team from a label of the input;
analyze a financial status of the team;
determine if the financial status of the team exceeds the estimate of the cost for implementation; and
determine, if the financial status of the team does not exceed the estimate of the cost for implementation, the input is invalid.

11. The computer program product of claim 8, comprising an AI engine configured to:
receive business requirements for a design for the system build;
receive historical data for the design;
receive core layer requirements for the design;
receive application specific requirements for the design; and
compile the business requirements, historical data, core layer requirements, and the application specific requirements into the plurality of architectural requirements for the system build.

12. The computer program product of claim 8, comprising a generative AI tool configured to:
receive an input file for the system build;
process the input file for a plurality of parameters for the system build;
request a plurality of additional parameters for the system build;
generate computer code using the plurality of parameters and plurality of additional parameters for the system build;
compile the computer code into the build output file; and
transmit the build output file.

13. The computer program product of claim 12, wherein the generative AI tool is integrated with at least one configuration management tool.

14. The computer program product of claim 13, wherein the generative AI is configured to:
analyze available data for incorrect data;
identify data of the available data that is incorrect data; and
flag the incorrect data of the available data for manual adjustment.

15. A method for automatic requirements capture and generation of system builds using artificial intelligence, the method comprising:
receiving a plurality of architectural requirements for a system build;
rendering an interactive graphical user interface (GUI) for display on user devices, wherein the GUI comprises information for a plurality of system builds;
receiving an input from a user device displaying the GUI, wherein the input comprises information for the system build;
validating the input for the system build;
transmitting, upon invalidation of the input, a notification of an invalid input to the user device;
transmitting, upon validation of the input, the input to networked devices associated with the system build;
receiving a build output file for the system build; and
storing the build output file in at least one memory device.

16. The method of claim 15, wherein validating the input comprises an AI model configured for:
analyzing each element of the input for incorrect data;
determining, if an element of the input is incorrect, the input is invalid;
analyzing a label of the input to determine a category, wherein at least one category is a design category;
analyzing, if the category is a design category, the input for elements of a design for the system build;
comparing the elements of the design against the plurality of architectural requirements; and
determining, if an element of the design does not meet an architectural requirement, the input is invalid.

17. The method of claim 16, wherein the AI model is configured for:
analyzing, if the category is a design category, design requirements for the input;
calculating an estimate of a cost for implementation;
extracting a team from a label of the input;
analyzing a financial status of the team;
determining if the financial status of the team exceeds the estimate of the cost for implementation; and
determining, if the financial status of the team does not exceed the estimate of the cost for implementation, the input is invalid.

18. The method of claim 15, comprising an AI engine configured for:
receiving business requirements for a design for the system build;
receiving historical data for the design;
receiving core layer requirements for the design;
receiving application specific requirements for the design; and
compiling the business requirements, historical data, core layer requirements, and the application specific requirements into the plurality of architectural requirements for the system build.

19. The method of claim 15, comprising a generative AI tool configured for:
receiving an input file for the system build;
processing the input file for a plurality of parameters for the system build;
requesting a plurality of additional parameters for the system build;
generating computer code using the plurality of parameters and plurality of additional parameters for the system build;
compiling the computer code into the build output file; and
transmitting the build output file.

20. The method of claim 19, wherein the generative AI is configured for:
analyzing available data for incorrect data;
identifying data of the available data that is incorrect data; and
flagging the incorrect data of the available data for manual adjustment.
